(19) United States
(12) Patent Application Publication
(10) Pub. No.: US 2008/0314440 A1
(43) Pub. Date: Dec. 25, 2008

(54) PHOTOVOLTAIC COLLECTION SYSTEMS, FRICTION DRIVES, AND METHOD FOR TRACKING THE SUN AND AVOIDING WIND DAMAGE

(76) Inventors: J. Christopher Clemens, Chapel Hill, NC (US); Charles R. Evans, II, Chapel Hill, NC (US); John B. Brashier, Raleigh, NC (US); Montie W. Roland, Apex, NC (US)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 12/127,468

(22) Filed: May 27, 2008

Related U.S. Application Data
(60) Provisional application No. 60/931,530, filed on May 24, 2007.

(51) Int. Cl. H01L 31/042

(52) U.S. Cl. 136/251

(57) ABSTRACT

Disclosed are photovoltaic collection systems, friction drives, and method for tracking the sun and avoiding wind damage without the use of complicated or expensive mechanical systems. In particular, disclosed is friction drive system for coupling a support beam supporting a photovoltaic collection assembly to a support pillar. The frictional drive system can include a plurality of wheels positioned for rotatably and pivotably coupling the support beam to the support pillar such that the support beam will slip with respect to the support pillar under application of a wind torque of a predetermined amount. Further, at least one motor can apply torques to the wheels for moving the support beam with respect to the support pillar.

### RELATED APPLICATIONS

This application claims the benefit of U.S. Provisional Patent Application Ser. No. 60/931,530, filed May 24, 2007; the disclosure of which is incorporated herein by reference in its entirety.

### TECHNICAL FIELD

The subject matter described herein relates generally to the field of solar energy collection and conversion. More particularly, the subject matter described herein relates to photovoltaic collection systems, friction drives, and method for tracking the sun and avoiding wind damage.

### BACKGROUND

The effectiveness of many devices for the conversion of solar energy is greatly increased through the used of a tracking system that positions the solar device to more directly receive the sun's rays. In particular, this increased effectiveness can be most readily observed with solar concentrating systems. Because solar concentrating systems use optics to focus sunlight onto a solar collector, the ability of such a system to follow the path of the sun precisely, or at least within about one degree or better, can greatly affect the efficiency of the system. Non-concentrating applications generally require less accuracy, so the ability of such systems to follow the sun's path is less important, but even these systems can experience substantial improvement in the amount of power produced by using a tracking system.

In addition, solar radiation is a dilute energy source, so large surface areas are often desirable to collect useful amounts of solar radiation even when a solar tracking system is incorporated to increase the efficiency. Although the optics and energy conversion components are usually optimized to be lightweight, the large surface areas can be exposed to wind loads that can oftentimes exceed the gravity loads. As a result, the tracking system mechanical requirements can often be driven by this wind loading. With traditional tracking systems, the potential for damage due to wind or load imbalance generally leads tracking system designers to implement large, robust, and expensive gear systems despite the fact that solar tracking is an inherently low-speed, low-acceleration task. Because solar energy is a dilute energy source, these large and expensive systems likewise dilute the cost-effectiveness of such solar systems, thereby inhibiting the commercial appeal of the technology.

Thus, in light of the factors that should be considered when creating a solar collection system, there exists a need for tracking systems, assemblies, and methods for directing a solar collection element towards the sun that can withstand the high wind loads without the use of complicated or expensive mechanical systems.

### SUMMARY

The subject matter described herein includes photovoltaic collection systems, friction drives, and method for tracking the sun and avoiding wind damage.

According to one aspect, the subject matter disclosed herein includes a photovoltaic collection system for tracking the sun and avoiding wind damage. The photovoltaic collection system can include a support pillar, a support beam coupled to the support pillar, at least one photovoltaic collection assembly mounted to the support beam, and a friction drive system for frictionally coupling the support beam to the support pillar. The friction drive system can be designed for applying torques to the support beam to move the photovoltaic collection assembly and for slipping under application of wind torque of a predetermined amount.

According to another aspect, the subject matter disclosed herein includes a friction drive system for frictionally coupling a support beam supporting a photovoltaic collection assembly to a support pillar. The frictional drive system can include a plurality of wheels positioned for frictionally coupling a support beam supporting a photovoltaic collection assembly to a support pillar. The support beam can be configured to slip with respect to the support pillar under application of a wind torque of a predetermined amount. In addition, at least one motor can be included for applying torques to the wheels for moving the support beam with respect to the support pillar.

According to yet another aspect, the subject matter disclosed herein includes a method for controlling the position of a photovoltaic collection assembly for sun tracking and avoiding wind torques. The method can include frictionally driving a photovoltaic collection assembly for sun tracking and allowing slippage of the photovoltaic collection assembly with respect to at least one support member assembly in response to torques of a predetermined amount being applied to the photovoltaic collection assembly.

### BRIEF DESCRIPTION OF THE DRAWINGS

Embodiments of the subject matter described herein will now be explained with reference to the accompanying drawings, of which:

FIG. 1 is a perspective view of a photovoltaic collection system according to an embodiment of the present subject matter;

FIG. 2 is a perspective view of a photovoltaic collection system according to another embodiment of the present subject matter;

FIG. 3 is a cut-away perspective view of a friction drive system according to an embodiment of the present subject matter;

FIG. 4 is a detailed cut-away perspective view of the friction drive system shown in FIG. 3;

FIG. 5 is a perspective view of a friction drive system according to another embodiment of the present subject matter;

FIG. 6 is a top cross-sectional view of the friction drive system shown in FIG. 5; and

FIG. 7 is an alternative top cross-sectional view of the friction drive system shown in FIG. 6.

### DETAILED DESCRIPTION

Reference will now be made in detail to possible embodiments of the present subject matter, one or more examples of which are shown in the figures. Each example is provided to explain the subject matter and not as a limitation. In fact, features illustrated or described as part of one embodiment can be used in another embodiment to yield still a further embodiment. It is intended that the present subject matter cover such modifications and variations.

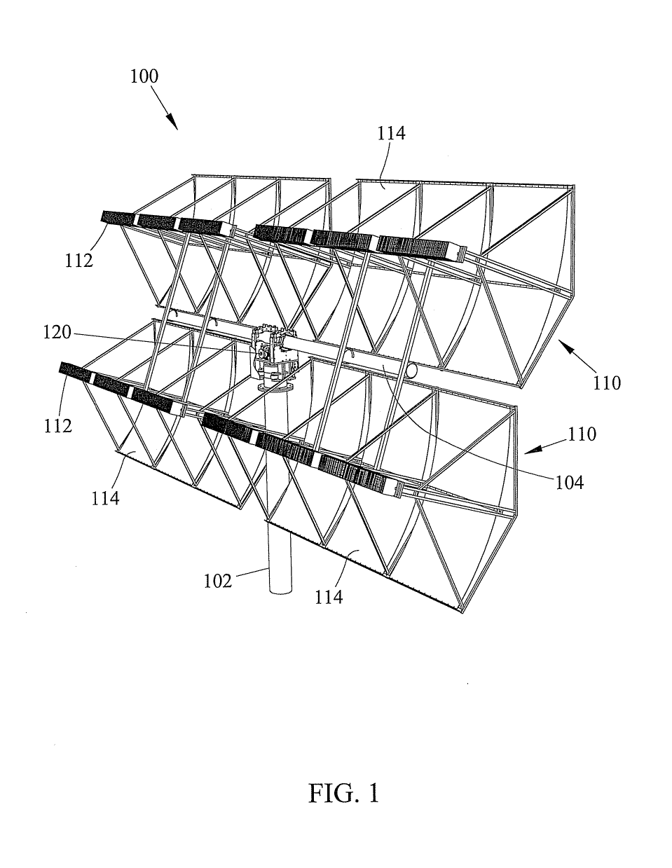

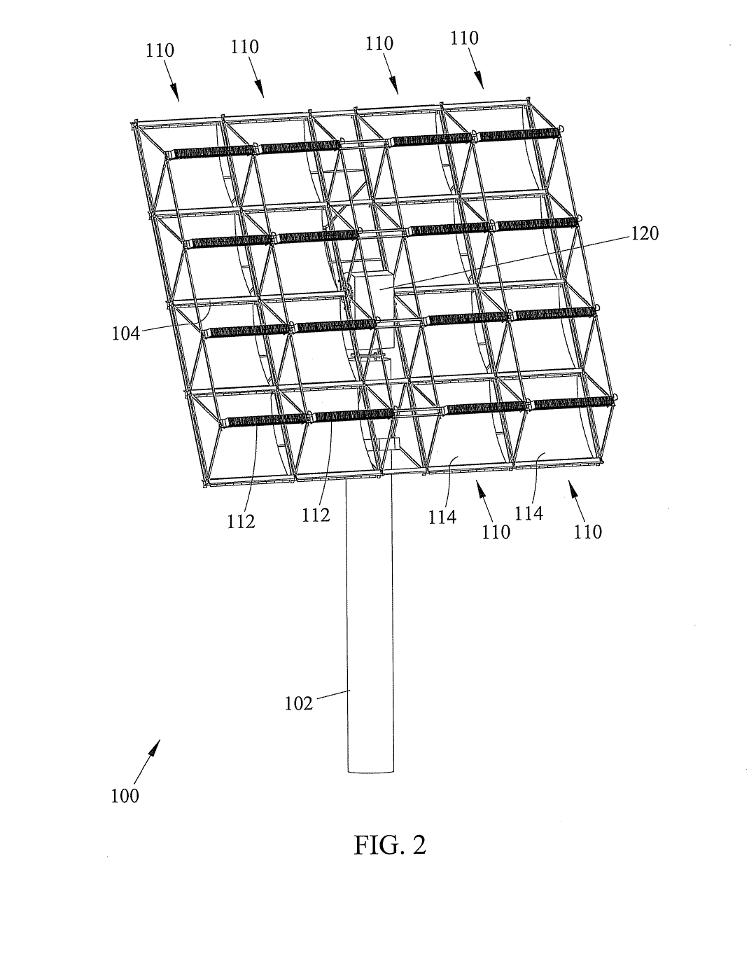

According to one aspect of the subject matter disclosed herein, provided is a photovoltaic collection system 100 for tracking the sun and avoiding wind damage. Referring to FIGS. 1 and 2, photovoltaic collection system 100 can include a support pillar 102, which can be firmly mounted in the ground or in some other rigid structure. A support beam 104 can be rotatably and pivotably coupled to support pillar 102, and at least one photovoltaic collection assembly 110 can be mounted to the support beam 104. Photovoltaic collection assembly 110 can include concentrating and/or non-concentrating solar elements. Specifically, photovoltaic collection assembly 110 can include at least one photovoltaic collector 112, either alone or in combination with a concentrating solar reflector 114. Photovoltaic collector 112 can comprise a plurality of photovoltaic cells arranged in a linear array. Concentrating solar reflector 114 can comprise a reflective sheet that is torqued at each end to form a fractional sinusoid shape. An example of such a system including concentrating solar reflectors 114 and photovoltaic collectors 112 is described in commonly owned, co-pending U.S. patent application Ser. No. 11/881,957, filed Jul. 30, 2007, the disclosure of which is incorporated herein by reference in its entirety.

Regardless of the specific configuration of photovoltaic collection assembly 110, photovoltaic collection system 100 will likely be subject to substantial wind loading. For instance, concentrating solar reflectors 114 can be relatively large in surface area as compared to photovoltaic collectors 112 and therefore can be subject to wind torques. Similarly, in photovoltaic collections systems without reflectors, photovoltaic collectors 112 themselves can have large surface areas that can be subject to wind torques. Conventional gear drives that do not allow for slippage between photovoltaic assembly supports and the drive system must therefore be engineered to withstand such torques. By being designed for such extreme loads, however, such systems are generally over-engineered for the task of driving photovoltaic collection assemblies for sun tracking.

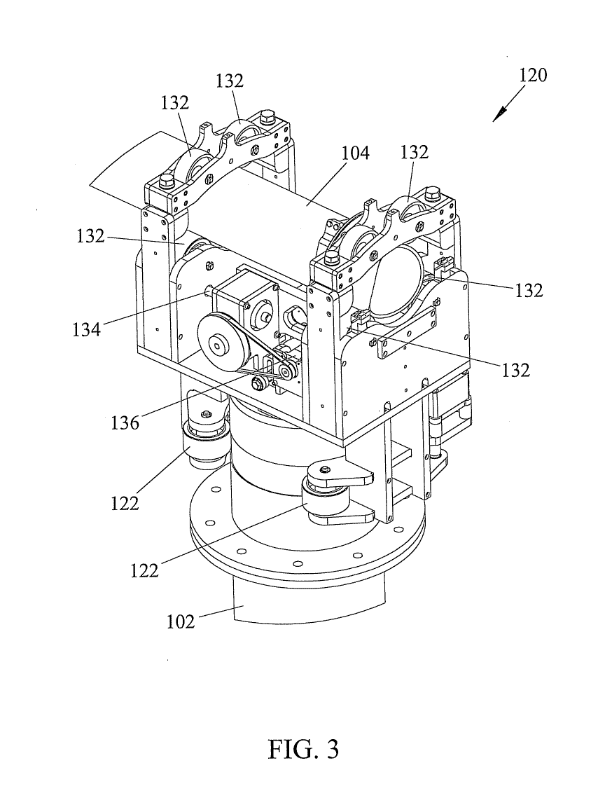

Accordingly, rather than utilizing a gear drive that does not allow slipping between the photovoltaic assembly supports and the drive system, photovoltaic collection system 100 can include a friction drive system 120, embodiments of which are shown in FIGS. 3-7. As is illustrated in these Figures, friction drive system 120 can be positioned to pivotably carry support beam 104 atop support pillar 102 as well as rotate support beam 104 in place. For instance, friction drive system 120 can include a central bearing or bushing (not shown) to enable the pivoting of friction drive system 120 relative to support pillar 102. Advantageously, friction drive system 120 can be configured to slip in torque overload conditions (e.g., high wind torque) and then recover automatically. As a result, friction drive system 120 disclosed herein need not be designed to withstand potentially large transient wind loads, but only the expected operating loads for positioning photovoltaic collection assembly 110. Accordingly, the disclosed system does not rely on a large, complicated, or expensive gear system. For instance, a small motor connected to the system with a high gear reduction ratio can be used in friction drive system 120. In this regard, both support pillar 102 and support beam 104 can be substantially round in section and sufficiently large both to carry the imposed loads and to serve as an element of the final reduction stage in friction drive system 120.

With regard to the operation of photovoltaic collection system 100, friction drive system 120 can be used to couple support beam 104 to support pillar 102. In this arrangement, friction drive system 120 can apply torques to support pillar 102 and/or support beam 104 to move photovoltaic collection assembly 110 mounted thereon. For example, friction drive system 120 can be adapted for applying torques to support pillar 102 and/or support beam 104 to change the angles of elevation and azimuth of photovoltaic collection assembly 110. In this arrangement, regardless of the orientation of support pillar 102, photovoltaic collection system 100 can still track the position of the sun because friction drive system 120 is movable in two perpendicular axes of motion.

In another arrangement, friction drive system 120 can be adapted for applying torques to support beam 104 to change the angles of declination and right ascension of photovoltaic collection assembly 110. This arrangement requires that support pillar 102 be mounted in a direction parallel to the Earth's axis of rotation. Despite this limitation, however, an equatorial mounted tracking system such as this need only pivot support beam 104 on support pillar 102 at a constant speed to track the movement of the sun over the course of a day. Support beam 104 can be rotated about its longitudinal axis to account for the changing position of the sun in the sky over the course of the year, but these changes need only be performed incrementally rather than continuously during the course of the day. As a result, an equatorial mount provides operating advantages over an altitude-azimuth mount, but it also requires greater precision in initial setup. In addition, mechanical or computer-based tracking programs can be used to operate friction drive system 120 to automate the multidirectional movement of an altitude-azimuth system, thereby diminishing much of the perceived burden compared to an equatorial system.

Regardless of the specific orientation of support pillar 102 and support beam 104, the frictional coupling of friction drive system 120 to support pillar 102 and support beam 104 can allow the connections to slip under application of wind torque of a predetermined amount. Stated otherwise, friction drive system 120 can be configured to engage and apply torques to support pillar 102 and support beam 104 through frictional connections rather than interlocking gears systems (e.g. using a ring gear) or other mechanical coupling mechanism. As a result, when loads that exceed the frictional force exerted by friction drive system 120 are applied to photovoltaic collection system 100, friction drive system 120 can decouple from support pillar 102 and/or support beam 104 and allow rotation of the elements to dampen the external torque. Friction drive system 120 can be designed to slip under the application of a torque having at least a predetermined value, which can be selected based on the torque capacity of friction drive system 120. For example, friction drive system 120 can be configured to slip under the application of a torque of around 600-700 foot-pounds. Once the over-torque condition is removed, friction drive system 120 can re-engage to return photovoltaic collection assembly 110 to the correct orientation without further mechanical intervention. Alternatively, in certain situations, it can be desirable to lock photovoltaic collection assembly 110 in an orientation that minimizes its aspect with respect to the wind. One such situation can be where wind conditions persist beyond the specified operating conditions for a prolonged period of time. For instance, photovoltaic collection assembly 110 can be oriented vertically to minimize the amount that either photovoltaic collector 112 or concentrating solar reflector 114 is acted on by the flow of the wind.

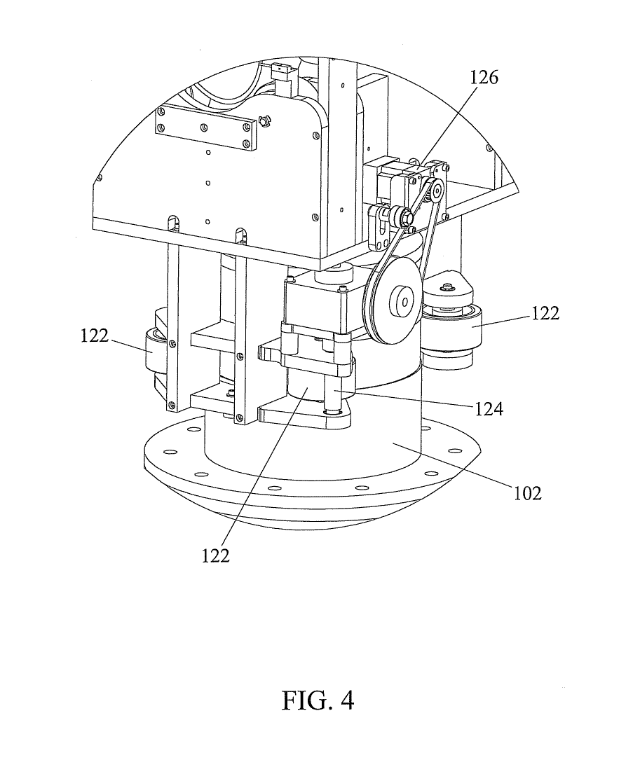

One embodiment of friction drive system 120 according to the present subject matter is depicted in FIGS. 3 and 4. In this embodiment, friction drive system 120 can include a plurality of first contact wheels 122 positioned for frictional contact with support pillar 102. One or more first drive shafts 124 can each be coupled to one or more of first contact wheels 122. The non-driven first contact wheels 122 can be free-rolling on sealed bearings or bushings. A first motor 126 (e.g., a worm drive) can be drivingly coupled to first drive shafts 124. For example, first motor 126 can be coupled to first drive shafts 124 through a high reduction gearbox. In this configuration, first motor 126 can be operated to drive the rotation of first drive shafts 124, which can cause the rotation of at least one of first contact wheels 122, which in turn apply a torque to pivot friction drive system 120 and support beam 104 about the axis of support pillar 102. In addition to pivoting support beam 104, first contact wheels 122 can also serve to support and stabilize friction drive system 120 and support beam 104 in their position on support pillar 102. In this regard, first contact wheels 122 provide a load path for forces resulting from the application of downward loads on support beam 104. As a result, the central bearing on which friction drive system 120 and support beam 104 pivots relative to support pillar 102 does not need to provide full support against the high torques that might result from such loads when support beam 104 is substantially long or heavy.

Friction drive system 120 can further include a plurality of second contact wheels 132 that can be positioned for frictional contact with support beam 104, one or more second drive shafts 134 that can each be coupled to one or more of second contact wheels 132, and a second motor 136 that can be drivingly coupled to second drive shafts 134. The operation of second motor 136 drives the rotation of second drive shafts 134, which drives the rotation of second contact wheels 132, which applies a torque to rotate support beam 104 about an axis. Further, second contact wheels 132 can serve not only to rotate support beam 104 but also to support the load of support beam 104 within friction drive system 120 on support pillar 102.

The amount of torque applied to support pillar 102 and support beam 104 is limited to the frictional forces that can be applied by first and second contact wheels 122 and 132. These frictional forces can be influenced by a number of factors, such as the weight of photovoltaic collection assembly 110 and support beam 104. Other factors that influence the frictional force include the number and positioning of first and second contact wheels 122 and 132 and the material or materials from which first and second contact wheels 122 and 132 are made. For instance, at least one of first contact wheels 122 and second contact wheels 132 can be composed of an elastomeric material, such as urethane, to provide a controllable frictional force between first and second contact wheels 122 and 132 and support pillar 102 and support beam 104, respectively. This material selection can be additionally useful because the elastomeric material can absorb vibrations and shock imposed by wind or other conditions. The shock absorbing properties and frictional coefficient can be adjusted by changing the specific material used to form first and second contact wheels 122 and 132, or by modifying the properties (e.g., density) of the material. Of course, it should be noted that the elasticity of elastomeric wheels can also detract from the ability to achieve fine pointing with photovoltaic collection system 100. The precision of pointing is less of a concern, however, for solar collection systems than it would be for other rotatably mounted devices, such as telescopes.

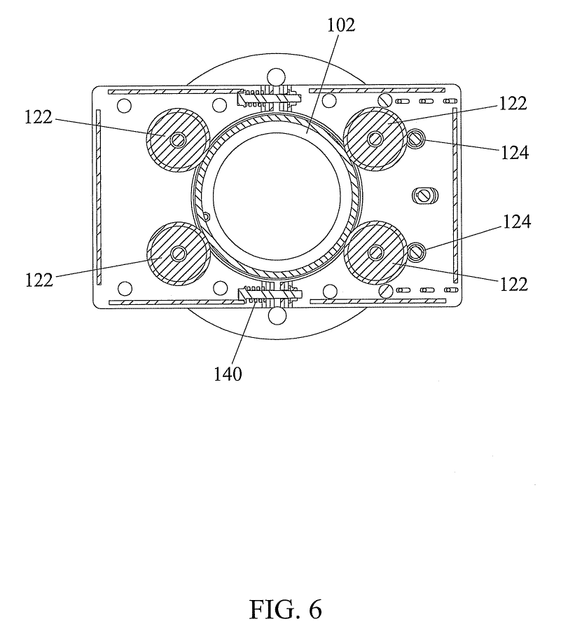

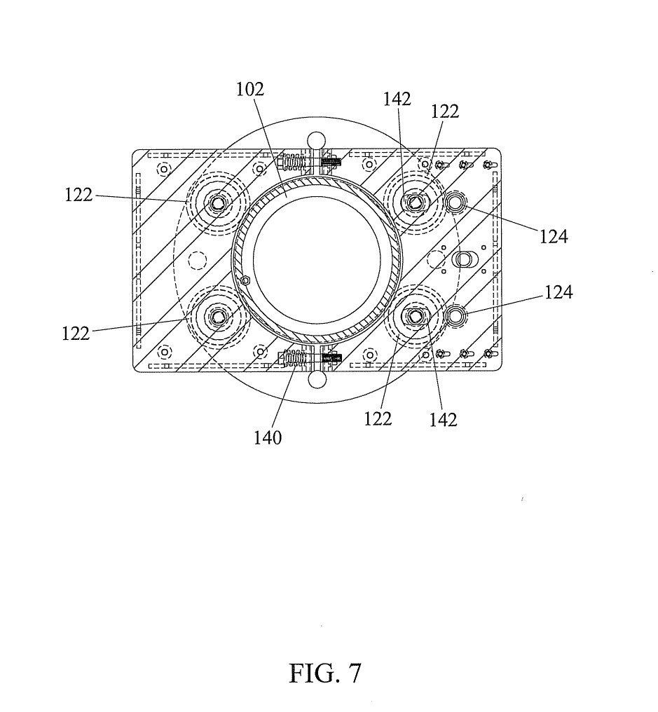

In addition, the position of at least one of first contact wheels 122 and second contact wheels 132 can be adjustable such that the normal force exerted on support pillar 102 and/or support beam 104, and thus the frictional force exerted, can otherwise be modified. This adjustability can be used to set the amount of applied force that will cause the frictional connection between friction drive system 120 and support pillar 102 and/or support beam 104 to slip. First contact wheels 122 and/or second contact wheels 132 can be adjustable by having the axle of one or more of first and second contact wheels 122 and 132 being positioned in a slotted hole 142. In this arrangement, the contact wheels can be releasably secured at a position in slotted hole 142 relative to support pillar 102 or support beam 104. Alternatively, as is depicted in FIGS. 6 and 7, the contact wheels can be coupled to movable assemblies that are spring-loaded such that the force of the engagement with support pillar 102 or support beam 104 is self-adjusting based on the tension of a spring element 140.

In yet a further alternative arrangement for the contact wheels coupled to one or more drive shafts, first and second contact wheels 122 and 132 can be allowed to move within slotted hole 142 to self-adjust such that the force between the contact wheels and respective drive shafts is balanced against the force between first and second contact wheels 122 and 132 and support pillar 102 or support beam 104 (to within a resolved vector component). In other words, first and second drive shafts 124 and 134 can be positioned such that the clearance between the drive shafts and either support pillar 102 or support beam 104 is smaller than the diameter of first or second contact wheels 122 or 132. As a result, the contact wheels can be squeezed between drive shafts and the corresponding structural element, thereby resulting in compression of the contact wheels and increased frictional force. The amount of the normal force exerted, and thus the amount of the frictional force, depends on the coefficient of friction between the surfaces, which can vary depending on the level of compression of the elastomeric material.

As an alternative to elastomeric contact wheels, at least some of first and second contact wheels 122 and 132 can be made of a more robust material (e.g., cast iron, steel). The contact wheels can be coated with an elastomeric material and still achieve some of the same characteristics of an entirely elastomeric wheel. Further, additional cost savings can be achieved by using non-load-bearing wheels composed of less-expensive materials, such as nylon, that can still captivate the structural members in place.

Similar to the options available for first and second contact wheels 122 and 132, first and second drive shafts 124 and 134 can also be constructed in a variety of ways to serve their intended purpose. For instance, first and second drive shafts 122 and 134 can be composed of an elastomeric material or coated in an elastomeric material (e.g., urethane). Alternatively, at least one of first drive shafts 124 and second drive shafts 134 can have a knurled outer surface to more easily engage respective contact wheels.

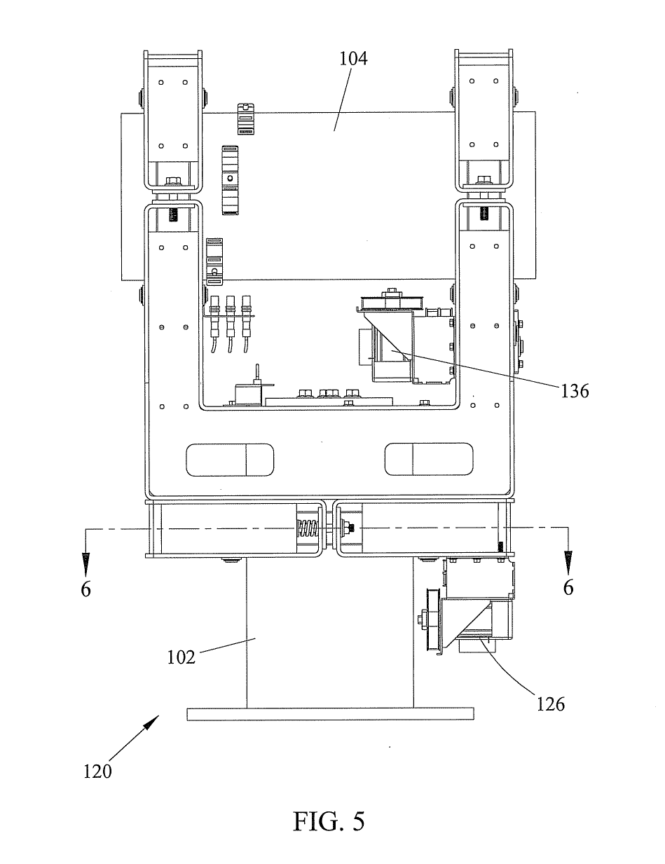

An alternative embodiment of friction drive system 120 is shown in FIGS. 5-7. In this embodiment, friction drive system 120 can be constructed from folded steel weldments. Similar to the first embodiment, friction drive system 120 can include a plurality of wheels positioned for frictionally coupling a support beam 104 supporting a photovoltaic collection assembly 110 to a support pillar 102. The support beam 104 can slip with respect to the support pillar 102 under application of a wind torque of a predetermined amount. At least one motor can be included for applying torques to the wheels for moving the support beam 104 with respect to the support pillar 102.

In particular, friction drive system 120 can include a plurality of first contact wheels 122 positioned for frictional contact with the support pillar 102, with one or more first drive shafts 124 each coupled to one of the first contact wheels 122. For example, the specific embodiment of friction drive system 120 shown in FIGS. 5-7 includes two urethane-coated first drive shafts 124. FIGS. 6 and 7 illustrate how the drive torque is communicated to support pillar 102 (depicted as a 10″ pipe). The two first contact wheels 122 on the right hand side of the figures can be captive in an assembly that is separate from the assembly that captivates the two first contact wheels 122 on the left. The two assemblies can be spring loaded against support pillar 102 such that the four contact wheels shown make firm contact with its surface. The compression of load spring 140 increases the contact force, allowing adjustment of the maximum frictional force that can be sustained before slipping. In this configuration, the rotation of first drive shafts 124 by first motor 126 frictionally drives two of first contact wheels 122, which in turn transfers a torque to support pillar 102, thereby pivoting friction drive system 120 and support beam 104 on support pillar 102.

Similarly, friction drive system 120 can include a plurality of second contact wheels (not shown in FIGS. 5-7) positioned for frictional contact with support beam 104, with one or more second drive shafts (not shown in FIGS. 5-7) each being coupled to one of the second contact wheels. The operation of a second motor 136 rotates the second drive shafts, which frictionally drives two of the second contact wheels, which in turn transfers a torque to support beam 104, thereby rotating support beam 104 within friction drive system 120 about a longitudinal axis.

Overall, the presently disclosed photovoltaic collection assembly 110 and friction drive system 120 can provide a substantial reduction in cost in solar tracking systems. First, the disclosed system eliminates the necessity of large gears and bearings from the assembly. As a result, only small wheel bearings or bushings are required. These components can be easily replaceable without disassembly of the entire unit. Moreover, because support pillar 102 and support beam 104 can both slip with respect to friction drive system 120 before breaking their respective drivetrains, the gearboxes used can be the minimum necessary to provide the required drive torques under expected operating conditions.

Accordingly, regardless of the specific configuration employed, the presently-disclosed subject matter can provide a method for controlling the position of a photovoltaic collection assembly 110 for sun tracking and avoiding breakage by wind torques. The method can involve frictionally driving photovoltaic collection assembly 110 for sun tracking and allowing slippage of photovoltaic collection assembly 110 with respect to at least one support member assembly (e.g., support pillar 102 and support beam 104) in response to torques of a predetermined amount being applied to photovoltaic collection assembly 110. More particularly, the method can involve positioning a plurality of first contact wheels 122 for frictional engagement with the support member assembly, coupling one or more first drive shafts 124 to at least one of first contact wheels 122, and drivingly coupling a first motor 126 to first drive shafts 124. Similarly, a plurality of second contact wheels 132 can be positioned for frictional engagement with the support member assembly, one or more second drive shafts 134 can be coupled to at least one of second contact wheels 132, and a second motor 136 can be drivingly coupled to second drive shafts 134.

With such an arrangement, frictionally driving a photovoltaic collection assembly for sun tracking can involve operating first motor 126 to apply torques to first drive shafts 124 and azimuthally move photovoltaic collection assembly 110, and operating second motor 136 to apply torques to second drive shafts 134 and elevationally move photovoltaic collection assembly 110. Alternatively, as noted above, the support member assembly can be oriented specifically so that one rotational axis is substantially parallel to the Earth's axis of rotation (i.e., an equatorial mount). In such an alternate configuration, frictionally driving a photovoltaic collection assembly for sun tracking can involve operating first motor 126 to apply torques to first drive shafts 124 and change the right ascension of photovoltaic collection assembly 110, and operating second motor 136 to apply torques to second drive shafts 134 and change the declination photovoltaic collection assembly 110.

It will be understood that various details of the presently disclosed subject matter may be changed without departing from the scope of the presently disclosed subject matter. Furthermore, the foregoing description is for the purpose of illustration only, and not for the purpose of limitation.

What is claimed is:

1. A photovoltaic collection system for tracking the sun and avoiding wind damage comprising:
a support pillar;
a support beam coupled to the support pillar;
at least one photovoltaic collection assembly mounted to the support beam; and
a friction drive system for frictionally coupling the support beam to the support pillar for applying torques to the support beam to move the photovoltaic collection assembly and for slipping under application of wind torque of a predetermined amount.

2. The photovoltaic collection system of claim 1, wherein friction drive system is adapted for applying torques to the support beam to change the angles of elevation and azimuth of the photovoltaic collection assembly.

3. The photovoltaic collection system of claim 1, wherein the friction drive system is adapted for applying torques to the support beam to change the angles of declination and right ascension of the photovoltaic collection assembly.

4. The photovoltaic collection system of claim 1, wherein the at least one photovoltaic collection assembly comprises at least one photovoltaic collector.

5. The photovoltaic collection system of claim 1, wherein the at least one photovoltaic collection assembly comprises at least one concentrating solar reflector.

6. The photovoltaic collection system of claim 1, wherein the friction drive system comprises:
a plurality of first contact wheels positioned for frictional contact with the support pillar;
a plurality of second contact wheels positioned for frictional contact with the support beam;
one or more first drive shafts each coupled to one or more of the first contact wheels;
one or more second drive shafts each coupled to one or more of the second contact wheels;
a first motor drivingly coupled to the first drive shafts; and
a second motor drivingly coupled to the second drive shafts.

7. The photovoltaic collection system of claim 6, wherein at least one of the first contact wheels and the second contact wheels are composed of an elastomeric material.

8. The photovoltaic collection system of claim 7, wherein at least one of the first contact wheels and the second contact wheels are composed of urethane.

9. The photovoltaic collection system of claim 6, wherein the position of at least one of the first contact wheels and the second contact wheels is adjustable.

10. The photovoltaic collection system of claim 6, wherein at least one of the first drive shafts and the second drive shafts has a knurled outer surface.

11. The photovoltaic collection system of claim 6, wherein at least one of the first drive shafts and the second drive shafts are coated with an elastomeric material.

12. The photovoltaic collection system of claim 11, wherein at least one of the first drive shafts and the second drive shafts are coated with urethane.

13. A friction drive system for frictionally coupling a support beam supporting a photovoltaic collection assembly to a support pillar, the frictional drive system comprising:
a plurality of wheels positioned for frictionally coupling a support beam supporting a photovoltaic collection assembly to a support pillar such that the support beam will slip with respect to the support pillar under application of a wind torque of a predetermined amount; and
at least one motor for applying torques to the wheels for moving the support beam with respect to the support pillar.

14. The friction drive system of claim 13, wherein the plurality of wheels comprise:
a plurality of first contact wheels positioned for frictional contact with the support pillar;
one or more first drive shafts each coupled to one of the first contact wheels;
a plurality of second contact wheels positioned for frictional contact with the support beam; and
one or more second drive shafts each coupled to one of the second contact wheels.

15. The friction drive system of claim 14, wherein the at least one motor comprises:
a first motor for applying torques to the first drive shafts for azimuthally moving the support beam; and
a second motor for applying toques to the second drive shafts for elevationally moving the support beam.

16. A method for controlling the position of a photovoltaic collection assembly for sun tracking and avoiding wind torques, the method comprising:
frictionally driving a photovoltaic collection assembly for sun tracking; and
allowing slippage of the photovoltaic collection assembly with respect to at least one support member assembly in response to torques of a predetermined amount being applied to the photovoltaic collection assembly.

17. The method of claim 16, wherein frictionally driving a photovoltaic collection assembly for sun tracking comprises:
positioning a plurality of first contact wheels for frictional engagement with the support member assembly;
coupling one or more first drive shafts to at least one of the first contact wheels;
drivingly coupling a first motor to the first drive shafts;
positioning a plurality of second contact wheels for frictional engagement with the support member assembly;
coupling one or more second drive shafts to at least one of the second contact wheels; and
drivingly coupling a second motor to the second drive shafts.

18. The method of claim 17, wherein frictionally driving a photovoltaic collection assembly for sun tracking comprises:
operating the first motor to apply torques to the first drive shafts and azimuthally move the photovoltaic collection assembly; and
operating the second motor to apply torques to the second drive shafts and elevationally move the photovoltaic collection assembly.
